(19) United States
(12) Patent Application Publication
(10) Pub. No.: US 2026/0269445 A1
(43) Pub. Date: Sep. 10, 2026

(54) SIGNAL TRANSMISSION DEVICE HAVING MULTILAYER STRUCTURE

(71) Applicant: M31 TECHNOLOGY CORPORATION, HSINCHU COUNTY (TW)

(72) Inventors: JUNG CHI HO, HSINCHU COUNTY (TW); CHANG-CHI CHANG, HSINCHU COUNTY (TW); KUAN-JEN SU, HSINCHU COUNTY (TW); PIN-HAO FENG, HSINCHU COUNTY (TW)

(21) Appl. No.: 19/074,262

(22) Filed: Mar. 7, 2025

(51) Int. Cl. H01P 3/02; H05K 1/11

(52) U.S. Cl. CPC H01P 3/088; H01P 3/082

(57) ABSTRACT

A signal transmission device includes a dielectric layer, a first signal layer, a second signal layer, and a set of signal lines. The dielectric layer is stacked between the first signal layer and the second signal layer. The set of signal lines, arranged in parallel along a predetermined direction, is configured to transmit a physical layer signal. The set of signal lines includes a first signal line, a second signal line, a third signal line and a fourth signal line. The first signal line is arranged in the first signal layer. The second signal line and the third signal line are arranged in the second signal layer. A distance from the fourth signal line to one of the first signal line and the third signal line is equal to a distance from the second signal line to the other of the first signal line and the third signal line.

### BACKGROUND

The present disclosure relates to impedance control and, more particularly, to a signal transmission device utilizing a multilayer structure to maintain impedance control for different physical layer protocols.

A system on chip (SoC) or processor can be integrated with various application interfaces, such as camera, display, and storage interfaces. Different application interfaces may utilize different physical layer (PHY) standards to accommodate diverse data transmission needs. Additionally, a single interface may need to support multiple PHY standards. For instance, to support camera modules with varying resolutions and frame rates, a camera interface may need to support both MIPI D-PHY and MIPI C-PHY standards. For high-speed data transmission applications, effective impedance control can reduce signal reflection, interference, and power consumption. However, providing effective impedance control across different PHY standards needs dedicated impedance control mechanisms for each PHY standard, leading to increased circuit complexity and manufacturing costs.

### SUMMARY

The described embodiments provide a signal transmission device utilizing a multilayer structure to maintain impedance control for different physical layer protocols.

Some embodiments described herein may include a signal transmission device. The signal transmission device includes a dielectric layer, a first signal layer, a second signal layer, and a set of signal lines. The dielectric layer is stacked between the first signal layer and the second signal layer. The set of signal lines is arranged in parallel along a predetermined direction, and is configured to transmit a physical layer signal. The set of signal lines includes a first signal line, a second signal line, a third signal line and a fourth signal line. The first signal line is arranged in the first signal layer. The second signal line and the third signal line are arranged in the second signal layer. A distance from the fourth signal line to one of the first signal line and the third signal line is equal to a distance from the second signal line to the other of the first signal line and the third signal line.

Some embodiments described herein may include a signal transmission device. The signal transmission device includes a plurality of signal layers, a first trio of signal lines, and a second trio of signal lines. The signal layers are stacked one above another. The first trio of signal lines is configured for transmitting first data associated with three-phase encoding. At least two signal lines in the first trio of signal lines are located in different signal layers. Each signal line in the first trio of signals line is arranged along a predetermined direction. The second trio of signal lines is configured for transmitting second data associated with three-phase encoding. At least two signal lines in the second trio of signal lines are located in different signal layers. Each signal line in the second trio of signals line is arranged along the predetermined direction. A distance from one signal line in the second trio of signal lines to one signal line in the first trio of signal lines is equal to a distance between the other two signal lines in the first trio of signal lines.

Some embodiments described herein may include a signal transmission device. The signal transmission device includes a first signal layer, a second signal layer, a first pair of signal lines, and a second pair of signal lines. The first signal layer and the second signal layer are stacked one above the other. The first pair of signal lines is configured for transmitting first data associated with differential signaling. A first signal line and a second signal line included in the first pair of signal lines are located in the first signal layer and the second signal layer respectively, and arranged along a predetermined direction. The second pair of signal lines is configured for transmitting second data associated with differential signaling. A third signal line and a fourth signal line included in the second pair of signals line are arranged along the predetermined direction. Three of the first signal line, the second signal line, the third signal line and the fourth signal line are equally spaced apart from each other.

With the use of the three-dimensional signal line configuration, the proposed signal transmission scheme can meet the combo requirements for both two-phase and three-phase signal transmission, thereby maintaining impedance consistency and signal integrity for both two-phase and three-phase signal transmission on shared routing traces.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary signal transmission system in accordance with some embodiments of the present disclosure.

FIG. 2 illustrates an implementation of the signal transmission system shown in FIG. 1 in accordance with some embodiments of the present disclosure.

FIG. 3 is a diagram illustrating an exemplary signal transmission device in accordance with some embodiments of the present disclosure.

FIG. 4 is a diagram illustrating an implementation of a cross-sectional structure taken along the line of FIG. 3 in accordance with some embodiments of the present disclosure.

FIG. 5A is a diagram illustrating another implementation of a cross-sectional structure taken along the line of FIG. 3 in accordance with some embodiments of the present disclosure.

FIG. 5B is a diagram illustrating another implementation of a cross-sectional structure taken along the line of FIG. 3 in accordance with some embodiments of the present disclosure.

FIG. 6A illustrates an implementation of the signal transmission device shown in FIG. 3 in accordance with some embodiments of the present disclosure.

FIG. 6B is a top view of the signal transmission device shown in FIG. 6A in accordance with some embodiments of the present disclosure.

FIG. 7A is a diagram illustrating the signal transmission device shown in FIG. 6A applied for two-phase signal transmission in accordance with some embodiments of the present disclosure.

FIG. 7B is a diagram illustrating the signal transmission device shown in FIG. 6A applied for three-phase signal transmission in accordance with some embodiments of the present disclosure.

FIG. 8A is a diagram illustrating frequency responses of S-parameters of the signal transmission device shown in FIG. 6A employed in two-phase signal transmission shown in FIG. 7A in accordance with some embodiments of the present disclosure.

FIG. 8B is a diagram illustrating frequency responses of S-parameters of the signal transmission device shown in FIG. 6A employed in three-phase signal transmission shown in FIG. 7B in accordance with some embodiments of the present disclosure.

FIG. 9 is a diagram illustrating a signal transmission device employing a two-dimensional signal line configuration in accordance with some embodiments of the present disclosure.

FIG. 10A is a diagram illustrating frequency responses of S-parameters of the signal transmission device shown in FIG. 9 employed in two-phase signal transmission in accordance with some embodiments of the present disclosure.

FIG. 10B is a diagram illustrating frequency responses of S-parameters of the signal transmission device shown in FIG. 9 employed in three-phase signal transmission in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure describes a signal transmission scheme compatible with both two-phase and three-phase signals. The signal transmission scheme can utilize a three-dimensional signal trace configuration to achieve impedance control, allowing two-phase and three-phase signal transmission to share the same signal lines while maintaining impedance consistency for both types of transmission. The two-phase signals can include, but are not limited to, MIPI D-PHY signals, while the three-phase signals can include, but are not limited to, MIPI C-PHY signals. For example, the proposed signal transmission scheme can be applied to MIPI C-PHY/D-PHY combo circuits. Further description is provided below.

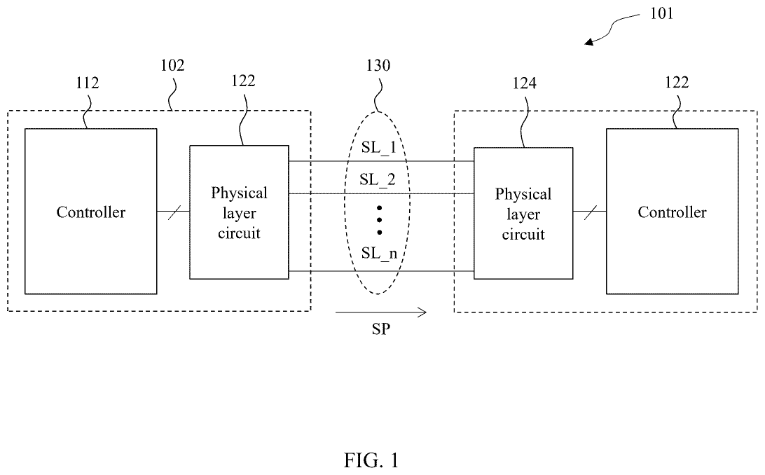

FIG. 1 is a diagram illustrating an exemplary signal transmission system in accordance with some embodiments of the present disclosure. The signal transmission system 101 includes a transmitter 102 and a receiver 104. The transmitter 102 is configured to transmit a physical layer signal SP to the receiver 104 via a signal transmission link 130. In the present embodiment, the transmitter 102 may include, but is not limited to, a controller 112 and a physical layer circuit 122. The physical layer circuit 122 is configured to convert a protocol layer signal coming from the controller 112 into the physical layer signal SP, and transmit the physical layer signal SP to the receiver 104 via the signal transmission link 130. The receiver 104 may include, but is not limited to, a controller 114 and a physical layer circuit 124. The physical layer circuit 124 is configured to receive the physical layer signal SP via the signal transmission link 130, and convert the physical layer signal SP into a protocol layer signal. The controller 114 is configured to process the protocol layer signal coming from the physical layer circuit 124.

The signal transmission link 130 includes a routing structure that is compatible with two-phase signal transmission and three-phase signal transmission. For example, the signal transmission link 130 may include n signal lines SL_1 to SL_n for transmitting the physical layer signal SP. The physical layer signal SP can be one or more two-phase signals that are implemented using pairs of differential signals compliant with the MIPI D-PHY standard. Alternatively, the physical layer signal SP can be one or more three-phase signals that are implemented using three-phase encoding and compliant with the MIPI C-PHY standard.

Consider a case where the physical layer signal SP includes one or more D-PHY signals. The controller 112, the physical layer circuit 122, the controller 114, and the physical layer circuit 124 can be implemented by a camera serial interface (CSI) transmitter (TX) controller (or a display serial interface (DSI) TX controller), a D-PHY TX circuit, a CSI receiver (RX) controller (or a DSI RX controller), and a D-PHY RX circuit, respectively. A portion or all of the n signal lines SL_1 to SL_n can be divided into j pairs of signal lines (also referred to as j differential pairs or j D-PHY lanes) arranged for transmitting the physical layer signal SP that includes D-PHY clock signal(s) and D-PHY data signal(s).

Consider another case where the physical layer signal SP includes one or more C-PHY signals. The controller 112, the physical layer circuit 122, the controller 114, and the physical layer circuit 124 can be implemented by a CSI TX controller (or a DSI TX controller), a C-PHY TX circuit, a CSI RX controller (or a DSI RX controller), and a C-PHY RX circuit, respectively. A portion or all of the n signal lines SL_1 to SL_n can be divided into k trios of signal lines (also referred to as k C-PHY lanes or k C-PHY trios) arranged for transmitting the physical layer signals SP that includes symbol(s) as defined by the MIPI C-PHY standard.

By way of example but not limitation, ten signal lines SL_1 to SL_10 (n=10) of the signal transmission link 130 can serve as five pairs of signal lines (j=5) that are configured to transmit four data signals and one clock signal; additionally, the signal lines SL_1 to SL_9 can serve as three trios of signal lines (k=3) that are configured to transmit three symbols. As another example, twelve signal lines SL_1 to SL_12 (n=10) of the signal transmission link 130 can serve as six pairs of signal lines (j=6) that are configured to transmit four data signals and two clock signals; additionally, the signal lines SL_1 to SL_12 can serve as four trios of signal lines (k=4) that are configured to transmit four symbols.

In some embodiments, the physical layer circuit 122 may be implemented using a MIPI C-PHY/D-PHY combo transmitter circuit; additionally or alternatively, the physical layer circuit 124 may be implemented using a MIPI C-PHY/D-PHY combo receiver circuit. In other words, the signal transmission link 130, the physical layer circuit 122 and the physical layer circuit 124 can be shared for both two-phase and three-phase signal transmission.

In some embodiments, the n signal lines SL_1 to SL_n of the signal transmission link 130 can be implemented using a three-dimensional trace configuration to achieve impedance consistency for both two-phase and three-phase signal transmission. In other words, the signal lines SL_1 to SL_n not only can be shared for two-phase and three-phase signal transmission, but also can maintain impedance consistency for both two-phase and three-phase signal transmission. Moreover, the signal lines SL_1 to SL_n of the signal transmission link 130 can be traces in a printed circuit board (PCB), traces in a package substrate, traces in an integrated circuit (IC) substrate, traces in redistribution layers (RDLs), traces in metal interconnect layers within a chip/die, or other traces between the physical layer circuits 122 and 124.

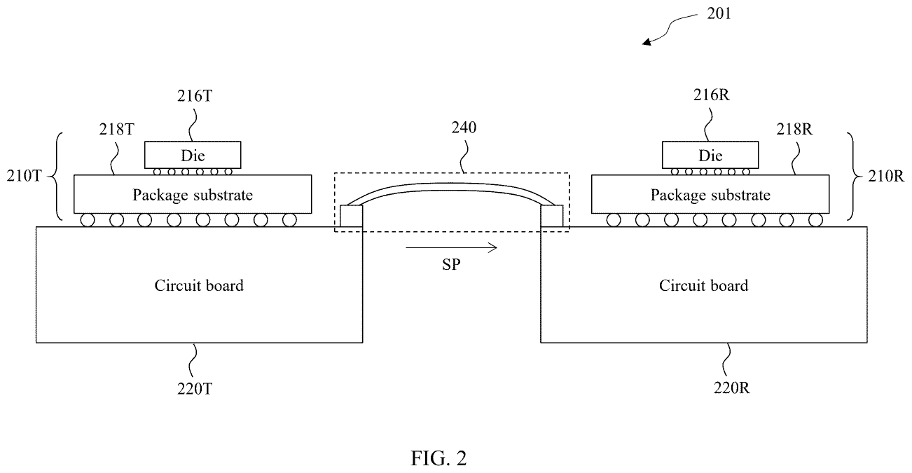

FIG. 2 illustrates an implementation of the signal transmission system 101 shown in FIG. 1 in accordance with some embodiments of the present disclosure. Referring to FIG. 2, the signal transmission system 201 may include, but is not limited to, a semiconductor package 210T and a circuit board 220T disposed on a transmitter side, a semiconductor package 210R and a circuit board 220R disposed on a receiver side, and a connection interface 240. A part or all of the semiconductor package 210T can be an embodiment of the transmitter 102 shown in FIG. 1; a part or all of the semiconductor package 210R can be an embodiment of the receiver 104 shown in FIG. 1; the circuit board 220T, the connection interface 240 and the circuit board 220R can be an embodiment of a part or all of the signal transmission link 130 shown in FIG. 1.

In the embodiment shown in FIG. 2, the semiconductor package 210T/210R may be implemented using (but not limited to) flip-chip ball grid array (BGA) technology. The semiconductor package 210T may include, but is not limited to, a die 216T and a package substrate 218T. The controller 112 and the physical layer circuit 122 shown in FIG. 1 can be implemented in the die 216T. Similarly, the semiconductor package 210R may include, but is not limited to, a die 216R and a package substrate 218R. The controller 114 and the physical layer circuit 124 shown in FIG. 1 can be implemented in the die 216R. In addition, the circuit board 220T/220R can be implemented using (but not limited to) a flexible printed circuit (FPC), a printed circuit board (PCB), a PCB load board, or an automatic test equipment (ATE) load board.

In operation, the physical layer signal SP can be transmitted from the die 216T to the die 216R though the package substrate 218T, the circuit board 220T, the connection interface 240, the circuit board 220R and the package substrate 218R. The package substrate 218T, the circuit board 220T, the connection interface 240, the circuit board 220R and the package substrate 218R can be an embodiment of the signal transmission link 130 shown in FIG. 1. For example, the signal lines SL_1 to SL_n shown in FIG. 1 that are laid out in three-dimensional space can be implemented in at least one of the package substrate 218T, the circuit board 220T, the circuit board 220R and the package substrate 218R.

In some embodiments, the proposed signal line structure can be applied to the die 216T/216R without departing from the scope of the present disclosure. For example, the traces within the die 216T/216R, or on-die interconnects, can be implemented based on the three-dimensional configuration of the signal lines SL_1 to SL_n shown in FIG. 1. In some embodiments, the semiconductor package 210T/210R can be implemented using various packaging technologies, such as chip-on-wafer-on-substrate (CoWoS), integrated fan-out (InFO), or wire-bonded (WB) BGA packaging technologies. The proposed signal line structure can be applied to a package substrate, an IC substrate, and/or RDLs between a package substrate and a die without departing from the scope of the present disclosure.

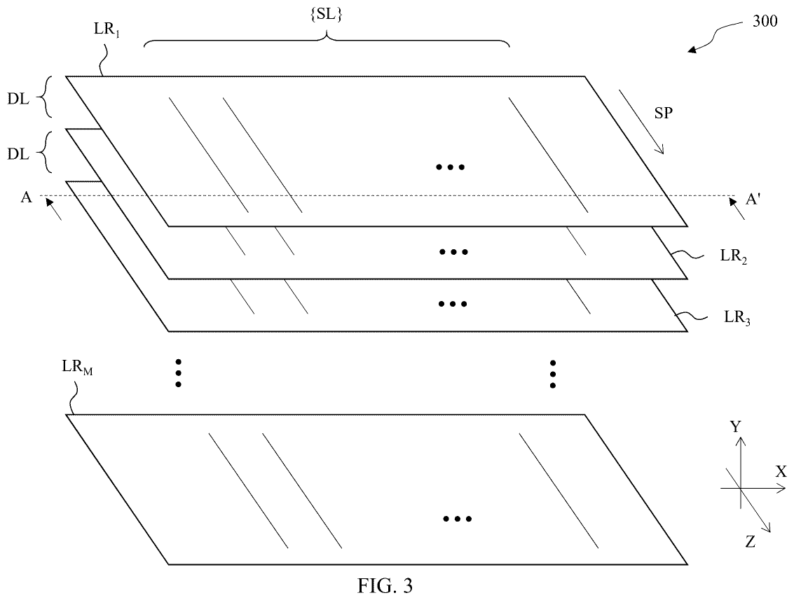

FIG. 3 is a diagram illustrating an exemplary signal transmission device in accordance with some embodiments of the present disclosure. The signal transmission device 300 employs a three-dimensional trace configuration that can be used to implement the signal lines SL_1 to SL_n shown in FIG. 1, which can be implemented in at least one of the package substrate 218T, the circuit board 220T, the circuit board 220R and the package substrate 218R shown in FIG. 2. In other words, the signal transmission device 300 can serve as an embodiment of at least a portion of the package substrate 218T, at least a portion of the circuit board 220T, at least a portion of the circuit board 220R, or at least a portion of the package substrate 218R shown in FIG. 2. Alternatively, the signal transmission device 300 can be used to implement the signal line configuration within the die 216T/216R shown in FIG. 2.

The signal transmission device 300 utilizes a multilayer structure for signal transmission. In the present embodiment, the signal transmission device 300 includes, but is not limited to, a plurality of signal layers LR₁ to LR_{M} (where M is an integer greater than 1), a plurality of dielectric layers DL, and a set of signal lines {SL}. The signal layers LR₁ to LR_{M} and the dielectric layers DL are stacked alternately. The set of signal lines {SL} is configured to transmit the physical layer signal SP, and can be an embodiment of the signal lines SL_1 to SL_n shown in FIG. 1. In addition, multiple signal lines within the set of signal lines {SL} can be distributed across multiple signal layers, and are arranged in parallel along a predetermined direction. For example, the multiple signal layers can be stacked one above another along the Y-axis, signal lines within each signal layer can be arranged along the X-axis and, and each signal line can extend along the Z-axis.

In the present embodiment, three signal lines located in two signal layers can be configured for three-phase signal transmission. In addition, the three signal lines and another signal line can form two pairs of signal lines for two-phase signal transmission. The distance between one of the three signal lines and the another signal line can be equal to or substantially equal to the distance between the remaining two signal lines of the three signal lines.

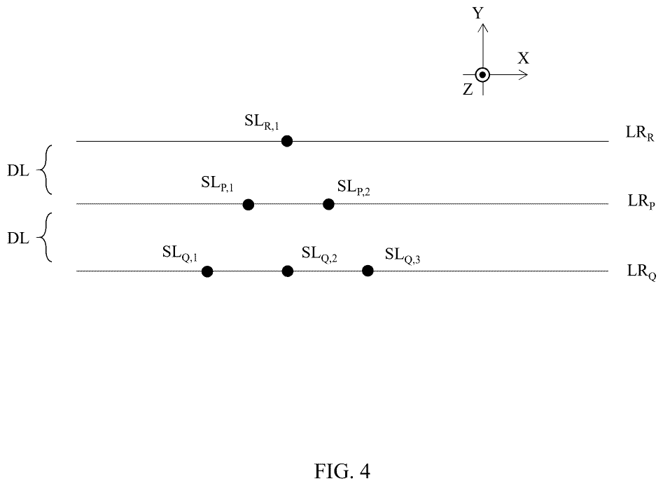

FIG. 4 is a diagram illustrating an implementation of a cross-sectional structure taken along the line A-A′ of FIG. 3 (i.e., a cross-sectional view in the XY-plane) in accordance with some embodiments of the present disclosure. In the present embodiment, the set of signal lines {SL} shown in FIG. 3 can include a signal line SL_{P,1} located in the signal layer LR_{P}, and signal lines SL_{Q,1} and SL_{Q,2} located in the signal layer LR_{Q}. The signal layer LR_{P}/LR_{Q} can be an embodiment of one of the signal layers LR₁ to LR_{M} shown in FIG. 3.

Referring to FIG. 4 and also to FIG. 3, three signal lines SL_{P,1}, SL_{Q,1} and SL_{Q,2} can be configured to transmit the data that is associated with three-phase encoding and contained in the physical layer signal SP. For example, the signal lines SL_{P,1}, SL_{Q,1} and SL_{Q,2} can serve as a trio of signal lines used for transmitting symbols defined by the C-PHY standard. The distance between the signal lines SL_{P,1} and SL_{Q,1} can be equal to or substantially equal to the distance between the signal lines SL_{P,1} and SL_{Q,2}. Thus, the differential impedance between the signal lines SL_{P,1} and SL_{Q,1} can be equal to or substantially equal to the differential impedance between the signal lines SL_{P,1} and SL_{Q,2}. Alternatively, the distances between any two of the signal lines SL_{P,1}, SL_{Q,1} and SL_{Q,2} can be equal or substantially equal; in other words, the signal lines SL_{P,1}, SL_{Q,1} and SL_{Q,2} are equally spaced apart from each other, forming an equilateral triangle in the XY-plane. Thus, each pair of signal lines selected from the signal lines SL_{P,1}, SL_{Q,1} and SL_{Q,2} can exhibit the same or substantially the same differential impedance.

In some embodiments, the signal lines SL_{P,1}, SL_{Q,1} and SL_{Q,2} can be combined with another signal line to form two pairs of signal lines, in which each pair of signal lines can be used for two-phase signal transmission. For example, the signal line SL_{Q,1} and one of the signal lines SL_{P,1} and SL_{Q,2} can serve as a first pair of signal lines, while another signal line and the other of the signal lines SL_{P,1} and SL_{Q,2} can serve as a second pair of signal lines. The distance between the first pair of signal lines can be equal to or substantially equal to the distance between the second pair of signal lines. In other words, the differential impedance between the first pair of signal lines can be equal to or substantially equal to the differential impedance between the second pair of signal lines. In some cases where the physical layer signal SP includes first data and second data, which are associated with differential signaling, the first pair of signal lines can be configured to transmit the first data (e.g. a D-PHY clock/data signal), and the second pair of signal lines can be configured to transmit the second data (e.g. a D-PHY clock/data signal).

For example, when the signal lines SL_{P,1} and SL_{Q,1} are used as a pair of signal lines for two-phase signal transmission, the signal line SL_{Q,2} can be combined with the signal line SL_{P,2} located in the signal layer LR_{P} to form another pair of signal lines for two-phase signal transmission. The distance between the signal lines SL_{P,1} and SL_{Q,1} can be equal to or substantially equal to the distance between the signal lines SL_{P,2} and SL_{Q,2}. Alternatively, when the signal lines SL_{P,1} and SL_{Q,1} are used as a pair of signal lines for two-phase signal transmission, the signal line SL_{Q,2} can be combined with the signal line SL_{Q,3} located in the signal layer LR_{Q} to form another pair of signal lines for two-phase signal transmission. The distance between the signal lines SL_{P,1} and SL_{Q,1} can be equal to or substantially equal to the distance between the signal lines SL_{Q,2} and SL_{Q,3}.

As another example, when the signal lines SL_{Q,1} and SL_{Q,2} are used as a pair of signal lines for two-phase signal transmission, the signal line SL_{P,1} can be combined with the signal line SL_{P,2} located in signal layer LR_{P} to form another pair of signal lines for two-phase signal transmission. The distance between the signal lines SL_{Q,1} and SL_{Q,2} can be equal to or substantially equal to the distance between the signal lines SL_{P,1} and SL_{P,2}. Alternatively, when the signal lines SL_{Q,1} and SL_{Q,2} are used as a pair of signal lines for two-phase signal transmission, the signal line SL_{P,1} can be combined with the signal line SL_{R,1} located in signal layer LR_{R} to form another pair of signal lines for two-phase signal transmission. The distance between the signal lines SL_{Q,1} and SL_{Q,2} can be equal to or substantially equal to the distance between the signal lines SL_{P,1} and SL_{R,1}. In the embodiment shown in FIG. 4, the distance between the signal layers LR_{P} and LR_{R} can be equal to or substantially equal to the distance between the signal layers LR_{P} and LR_{Q}.

In some embodiments, the differential impedance between any two signal lines in each trio of signal lines used for three-phase signal transmission can be equal to or substantially equal to the differential impedance between each pair of signal lines used for two-phase signal transmission. For example, the distance between any two signal lines in each trio of signal lines can be equal to or substantially equal to the distance between each pair of signal lines.

Consider a case where the signal lines SL_{P,1}, SL_{Q,1} and SL_{Q,2} are equidistant from each other, forming vertices of an equilateral triangle with side length D in the XY-plane. When used for two-phase signal transmission, the signal lines SL_{P,1}, SL_{Q,1} and SL_{Q,2}, together with an additional signal line, can form two pairs of signal lines. The additional signal line is at a distance equal to the side length D from one of the signal lines SL_{P,1}, SL_{Q,1} and SL_{Q,2}. For example, the additional signal line can be the signal line SL_{R,1} located in the signal layer LR_{R}; the signal lines SL_{R,1} and SL_{P,1} can form a pair of signal lines. As another example, the additional signal line can be the signal line SL_{P,2} located in the signal layer LR_{P}; the signal lines SL_{P,2} and SL_{P,1} (or the signal lines SL_{P,2} and SL_{Q,2}) can form a pair of signal lines. As still another example, the additional signal line can be the signal line SL_{Q,3} located in the signal layer LR_{Q}; the signal lines SL_{Q,3} and SL_{Q,2} can form a pair of signal lines. In other words, the additional signal line can be a vertex of an equilateral triangle in the XY-plane.

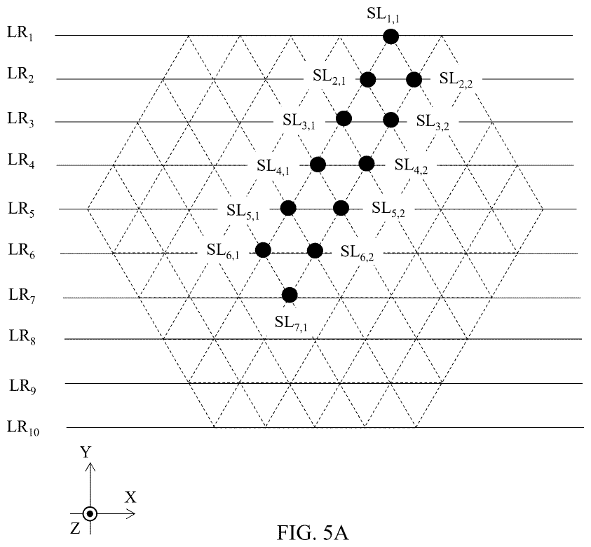

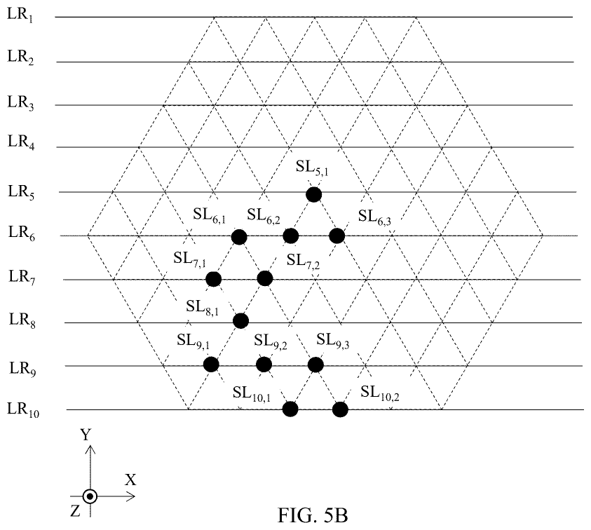

In some embodiments, the cross-sectional view of the proposed signal line structure can be described using triangular grid cells. FIG. 5A is a diagram illustrating another implementation of a cross-sectional structure taken along the line A-A′ of FIG. 3 in accordance with some embodiments of the present disclosure. The signal line layout shown in FIG. 5A is implemented based on the structure shown in FIG. 4, and is compatible with both two-phase and three-phase signal transmission.

Referring to FIG. 5A and also to FIG. 3, the set of signal lines {SL} may include, but is not limited to, twelve signal lines that can be distributed across seven of ten signal layers LR₁ to LR₁₀ (i.e. the signal layers LR₁ to LR₇). The distances between any two adjacent signal layers can be substantially equal. Each signal line can be used for both three-phase and two-phase signal transmission, and can be located at a vertex of an equilateral triangle in the XY-plane.

By way of example but not limitation, when the set of signal lines {SL} is used for three-phase signal transmission (e.g. C-PHY signal transmission), the signal lines SL_{1,1}, SL_{2,1} and SL_{2,2} can serve as a first trio of signal lines, the signal lines SL_{3,1}, SL_{3,2} and SL_{4,2} can form serve as a second trio of signal lines, the signal lines SL_{4,1}, SL_{5,1} and SL_{5,2} can serve as a third trio of signal lines, and the signal lines SL_{6,1}, SL_{6,2} and SL_{7,1} can serve as a fourth trio of signal lines. When the set of signal lines {SL} is used for two-phase signal transmission (e.g. D-PHY signal transmission), the signal lines SL_{1,1} and SL_{2,1} can serve as a first pair of signal lines, the signal lines SL_{2,2} and SL_{3,2} can serve as a second pair of signal lines, the signal lines SL_{3,1} and SL_{4,1} can serve as a third pair of signal lines, the signal lines SL_{4,2} and SL_{5,2} can serve as a fourth pair of signal lines, the signal lines SL_{5,1} and SL_{6,1} can serve as a fifth pair of signal lines, and the signal lines SL_{6,2} and SL_{7,1} can serve as a sixth pair of signal lines.

FIG. 5B is a diagram illustrating another implementation of a cross-sectional structure taken along the line A-A′ of FIG. 3 in accordance with some embodiments of the present disclosure. The signal line layout shown in FIG. 5B is implemented based on the structure shown in FIG. 4, and is compatible with both two-phase and three-phase signal transmission.

Referring to FIG. 5B and also to FIG. 3, the set of signal lines {SL} may include, but is not limited to, twelve signal lines that can be distributed across six of ten signal layers LR₁ to LR₁₀ (i.e. the signal layers LR₅ to LR₁₀). The distances between any two adjacent signal layers can be substantially equal. Each signal line can be used for both three-phase and two-phase signal transmission, and can be located at a vertex of an equilateral triangle in the XY-plane.

By way of example but not limitation, when the set of signal lines {SL} is used for three-phase signal transmission (e.g. C-PHY signal transmission), the signal lines SL_{5,1}, SL_{6,2} and SL_{6,3} can serve as a first trio of signal lines, the signal lines SL_{6,1}, SL_{7,1} and SL_{7,2} can form serve as a second trio of signal lines, the signal lines SL_{8,1}, SL_{9,1} and SL_{9,2} can serve as a third trio of signal lines, and the signal lines SL_{9,3}, SL_{10,1} and SL_{10,2} can serve as a fourth trio of signal lines. When the set of signal lines {SL} is used for two-phase signal transmission (e.g. D-PHY signal transmission), the signal lines SL_{5,1} and SL_{6,3} can serve as a first pair of signal lines, the signal lines SL_{6,2} and SL_{7,2} can serve as a second pair of signal lines, the signal lines SL_{8,1} and SL_{9,1} can serve as a third pair of signal lines, the signal lines SL_{9,2} and SL_{10,1} can serve as a fourth pair of signal lines, the signal lines SL_{9,3} and SL_{10,2} can serve as a fifth pair of signal lines, and the signal lines SL_{9,3} and SL_{10,2} can serve as a sixth pair of signal lines. Alternatively, the signal lines SL_{9,2} and SL_{9,3} can serve as the fifth pair of signal lines, and the signal lines SL_{10,1} and SL_{10,2} can serve as the sixth pair of signal lines.

Note that the signal line configurations shown in FIG. 4, FIG. 5A and FIG. 5B are provided for illustrative purposes, and are not intended to limit the scope of the present disclosure. In some embodiments, at least two signal lines in a trio of signal lines can be located in different signal layers. For example, each signal line in a trio of signal lines can be located in a different signal layer. In some embodiments, triangular grid points can be utilized to configure signal lines that are shared for both two-phase and three-phase signal transmission. The proposed signal line configuration can achieve highly flexible geometric arrangements of signal lines based on triangular grid points. In some embodiments, more than one dielectric layer may be placed between two signal layers. In some embodiments, one or more shield lines/traces may be placed between two signal lines that are arranged in the same signal layer or in different signal layers. For example, one or more signal layers may be formed between two adjacent signal layers shown in FIG. 4, FIG. 5A or FIG. 5B; as another example, one or more dielectric layers may be formed between two adjacent signal layers shown in FIG. 4, FIG. 5A or FIG. 5B; as still another example, one or more shield traces that are electrically connected to ground can be placed between two adjacent signal layers shown in FIG. 4, FIG. 5A or FIG. 5B.

To facilitate understanding of the proposed signal transmission scheme, some embodiments are given below and described with MIPI C-PHY/D-PHY combo applications. However, these embodiments are provided for illustrative purposes, and are not intended to limit the scope of the present disclosure. Those skilled in the art will appreciate that other implementations of the signal line configuration shown in FIG. 3 are within the contemplated scope of this disclosure.

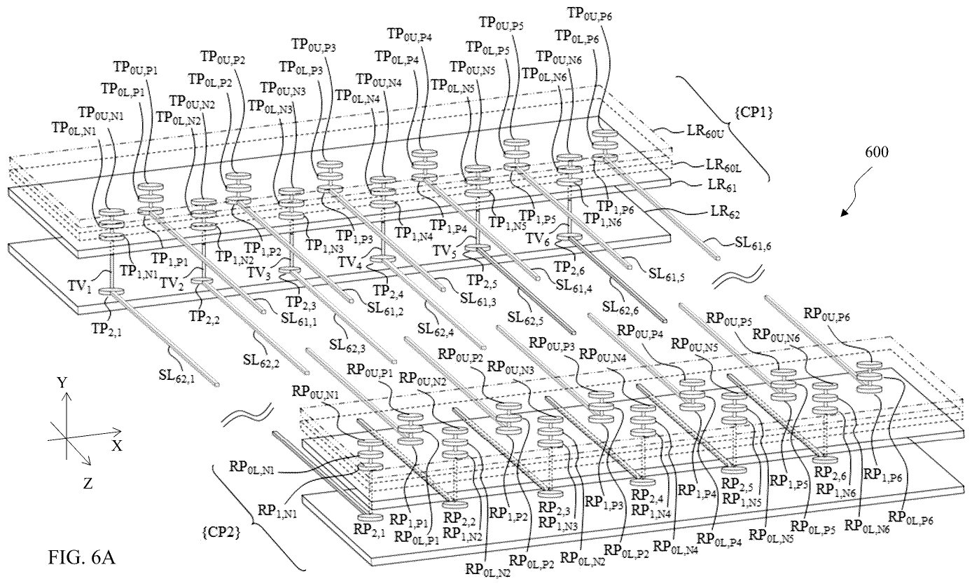

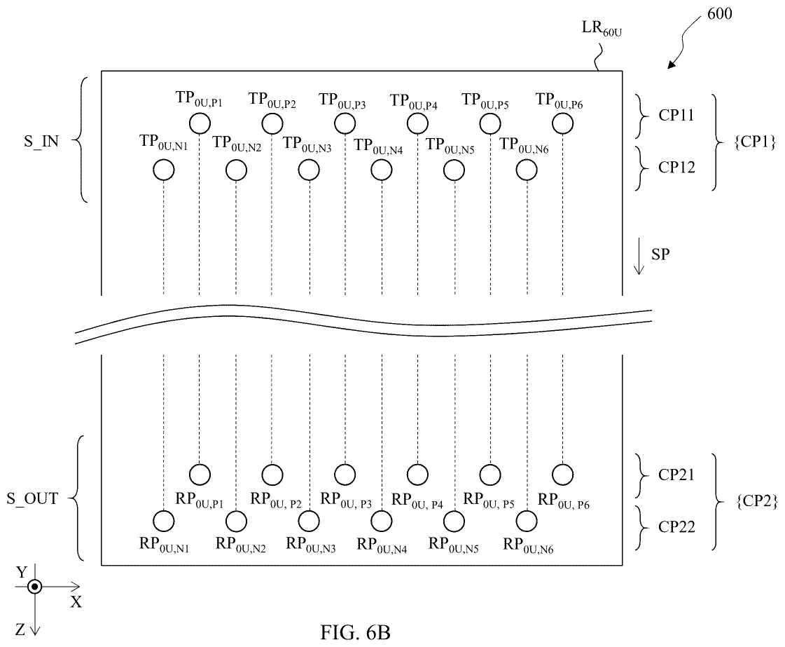

FIG. 6A illustrates an implementation of the signal transmission device 300 shown in FIG. 3 in accordance with some embodiments of the present disclosure. The signal transmission device 600 may include, but is not limited to, a signal layer LR₆₁, a signal layer LR₆₂, and a plurality of signal lines SL_{61,1} to SL_{61,6} and SL_{62,1} to SL_{62,6}. The signal layer LR₆₁/LR₆₂ can be an embodiment of one of the signal layers LR₁ to LR_{M} shown in FIG. 3, and the signal lines SL_{61,1} to SL_{61,6} and SL_{62,1} to SL_{62,6} can be an embodiment of at least part of the set of signal lines {SL} shown in FIG. 3. The signal lines SL_{61,1} to SL_{61,6} are arranged in the signal layer LR₆₁, and the signal lines SL_{62,1} to SL_{62,6} are arranged in the signal layer LR₆₂. The signal lines SL_{61,1} to SL_{61,6} and SL_{62,1} to SL_{62,6} may have equal or substantially equal lengths to maintain good impedance consistency.

The signal transmission device 600 may further include a plurality of conductive pads arranged in the signal layer LR₆₁ (e.g. the conductive pads TP_{1,P1} to TP_{1,P6}, TP_{1,N1} to TP_{1,N6}, RP_{1,P1} to RP_{1,P6}, and RP_{1,N1} to RP_{1,N6}) and a plurality of conductive pads arranged in the signal layer LR₆₂ (e.g. the conductive pads TP_{2,1} to TP_{2,6} and RP_{2,1} to RP_{2,6}). Two ends of the signal line SL_{61,i} are connected to the conductive pads TP_{1,Pi} and RP_{1,Pi} respectively, and two ends of each signal line SL_{62,i} are connected to the conductive pads TP_{2,i} and RP_{2,i} respectively, where i=1, 2, . . . , 6. In addition, the signal transmission device 600 may further include a plurality of conductive vias TV₁ to TV₆. The conductive via TVᵢ penetrates through the dielectric layer DL to electrically connect the conductive pad TP_{1,Ni} to the conductive pad TP_{2,i} or to one end of the signal line SL_{62,i}, where i=1, 2, . . . , 6. Similarly, the conductive pad RP_{1,Ni} is electrically connected to the conductive pad RP_{2,i}, or to the other end of the signal line SL_{62,i}, through a corresponding conductive via penetrating though the dielectric layer DL, where i=1, 2, . . . , 6.

In the present embodiment, additional signal layers can be stacked on top of the signal layer LR₆₁. By way of example but not limitation, the signal transmission device 600 may further include the signal layers LR_{60U} and LR_{60L} stacked on top of the signal layer LR₆₁. The conductive pad TP_{0U,Pi} in the signal layer LR_{60U} can be electrically connected to the conductive pad TP_{1,Pi} in the signal layer LR₆₁ through a conductive via (connected between the signal layers LR_{60U} and LR_{60L}), a conductive pad TP_{0L,Pi} (located in the signal layer LR_{60L}) and another conductive via (connected between the signal layers LR_{60L} and LR₆₁), where i=1, 2, . . . , 6. Similarly, conductive pads TP_{0U,Ni} in the signal layer LR_{60U} can be electrically connected to the conductive pad TP_{1,Ni} in the signal layer LR₆₁ through a conductive via (connected between the signal layers LR_{60U} and LR_{60L}), a conductive pad TP_{0L,Ni} (located in signal layer LR_{60L}) and another conductive via (connected between the signal layers LR_{60L} and LR₆₁), where i=1, 2, . . . , 6.

FIG. 6B is a top view of the signal transmission device 600 shown in FIG. 6A in accordance with some embodiments of the present disclosure. Referring to FIG. 6A and FIG. 6B, the physical layer signal SP can be input to the input side S_IN, coupled to the output side S_OUT via the signal lines SL_{61,1} to SL_{61,6} and SL_{62,1} to SL_{62,6} in the internal layers of the multilayer structure, and output from the output side S_OUT. In operation, the physical layer signal SP can be sent from the signal layer LR_{60U} to the signal layer LR₆₁/LR₆₂ through a plurality of conductive paths {CP1} at the input side S_IN, then coupled to the output side S_OUT via the signal lines SL_{61,1} to SL_{61,6} and SL_{62,1} to SL_{62,6}, and transmitted from the signal layer LR₆₁/LR₆₂ to the signal layer LR_{60U} at the output side S_OUT via a plurality of conductive paths {CP2}. The conductive paths {CP1}/{CP2} can be considered as vertical signal transmission paths for the physical layer signal SP, and the signal lines SL_{61,1} to SL_{61,6} and SL_{62,1} to SL_{62,6} can be considered as horizontal signal transmission paths for the physical layer signal SP.

The conductive paths {CP1} include a plurality of conductive paths CP11 connected to the signal lines SL_{61,1} to SL_{61,6} and multiple conductive paths CP12 connected to the signal lines SL_{62,1} to SL_{62,6}. The conductive path CP11 includes the conductive pads TP_{0U,Pi}, the conductive via connected between the conductive pads TP_{0U,Pi} and TP_{0L,Pi}, the conductive pad TP_{0L,Pi}, the conductive via connected between the conductive pads TP_{0L,Pi} and TP_{1,Pi}, and the conductive pad TP_{1,Pi}, where i=1, 2, . . . , 6. The conductive path CP12 includes the conductive pad TP_{0U,Ni}, the conductive via connected between the conductive pads TP_{0U,Ni} and TP_{0L,Ni}, the conductive pad T_{P0L}, _{Ni}, the conductive via connected between the conductive pads TP_{0L}, _{Ni} and TP_{1,Ni}, the conductive pad TP_{1,Ni}, the conductive via TVᵢ, and the conductive pad TP_{2,i}, where i=1, 2, . . . , 6. In the present embodiment, the conductive path CP11/CP12 can be vertically oriented relative to the signal layer LR₆₀. For example, the conductive vias included in conductive paths CP11/CP12 can extend along the Y-axis.

In the present embodiment, the configuration of the conductive paths {CP1} in the XZ-plane can correspond to the configuration of signal lines SL_{61,1} to SL_{61,6} and SL_{62,1} to SL_{62,6} in the XY-plane, thus maintaining consistent impedance between multiple signal transmission paths across different signal layers at the input side S_IN. For example, from the top view of signal layer LR₆₀, the conductive paths CP11 connected to the signal lines SL_{61,1} to SL_{61,6} are substantially at the same the Z-axis positions, and the conductive paths CP12 connected to the signal lines SL_{62,1} to SL_{62,6} are substantially at the same the Z-axis positions. The conductive paths CP12 are closer to the output side S_OUT than the conductive paths CP11. In addition, the configuration of the conductive pads TP_{0U,P1} to TP_{0U,P6} and TP_{0U,N1} to TP_{0U,N6} in the signal layer LR_{60U} can correspond to the configuration of the signal lines SL_{61,1} to SL_{61,6} and SL_{62,1} to SL_{62,6} in the XY-plane; the configuration of the conductive pads TP_{0L,P1} to TP_{0L,P6} and TP_{0L,N1} to TP_{0L,N6} in the signal layer LR_{60L} (or the conductive pads TP_{1,P1} to TP_{1,P6} and TP_{1,N1} to TP_{1,N6} in the signal layer LR₆₁) can correspond to the configuration of the signal lines SL_{61,1} to SL_{61,6} and SL_{62,1} to SL_{62,6} in the XY-plane; the configuration of the conductive vias connected between the signal layers LR_{60U} and LR_{60L} (or the conductive vias connected between the signal layers LR_{60L} and LR₆₁) in the XZ-plane can correspond to the configuration of the signal lines SL_{61,1} to SL_{61,6} and SL_{62,1} to SL_{62,6} in the XY-plane. Further description is provided later.

Similarly, the conductive paths {CP2} include a plurality of conductive paths CP21 connected to the signal lines SL_{61,1} to SL_{61,6} and multiple conductive paths CP22 connected to the signal lines SL_{62,1} to SL_{62,6}. The conductive path CP21 includes the conductive pads RP_{0U,Pi}, the conductive via connected between the conductive pads RP_{0U,Pi} and RP_{0L,Pi}, the conductive pad RP_{0L}, _{Pi}, the conductive via connected between the conductive pads RP_{0L}, _{Pi} and RP_{1,Pi}, and the conductive pad RP_{1,Pi}, where i=1, 2, . . . , 6. The conductive path CP22 includes the conductive pad RP_{0U,Ni}, the conductive via connected between the conductive pads RP_{0U,Ni} and RP_{0L,Ni}, the conductive pad R_{P0L,Ni}, the conductive via connected between the conductive pads RP_{0L,Ni} and RP_{1,Ni}, the conductive pad RP_{1,Ni}, the conductive via connected between the conductive pads RP_{1,Ni} and RP_{2,i}, and the conductive pad RP_{2,i}, where i=1, 2, . . . , 6. In the present embodiment, the conductive path CP21/CP22 can be vertically oriented relative to the signal layer LR₆₀. For example, the conductive vias included in conductive paths CP21/CP22 can extend along the Y-axis.

The configuration of the conductive paths {CP2} in the XZ-plane can correspond to the configuration of signal lines SL_{61,1} to SL_{61,6} and SL_{62,1} to SL_{62,6} in the XY-plane, thus maintaining consistent impedance between multiple signal transmission paths across different signal layers at the output side S_OUT. For example, from the top view of signal layer LR₆₀, the conductive paths CP21 connected to the signal lines SL_{61,1} to SL_{61,6} are substantially at the same the Z-axis positions, and the conductive paths CP22 connected to the signal lines SL_{62,1} to SL_{62,6} are substantially at the same the Z-axis positions. The conductive paths CP21 are closer to the input side S_IN than the conductive paths CP22. In addition, the configuration of the conductive pads RP_{0U,P1} to RP_{0U,P6} and RP_{0U,N1} to RP_{0U,N6} in the signal layer LR_{60U} can correspond to the configuration of the signal lines SL_{61,1} to SL_{61,6} and SL_{62,1} to SL_{62,6} in the XY-plane; the configuration of the conductive pads RP_{0L,P1} to RP_{0L,P6} and RP_{0L,N1} to RP_{0L,N6} in the signal layer LR_{60L} (or the conductive pads RP_{1,P1} to RP_{1,P6} and RP_{1,N1} to RP_{1,N6} in the signal layer LR₆₁) can correspond to the configuration of the signal lines SL_{61,1} to SL_{61,6} and SL_{62,1} to SL_{62,6} in the XY-plane; the configuration of the conductive vias connected between the signal layers LR_{60U} and LR_{60L} (or the conductive vias connected between the signal layers LR_{60L} and LR₆₁) in the XZ-plane can correspond to the configuration of the signal lines SL_{61,1} to SL_{61,6} and SL_{62,1} to SL_{62,6} in the XY-plane. Further description is provided later.

Note that the signal line configuration shown in FIG. 6A is compatible with both two-phase and three-phase signal transmission. For example, when the signal lines SL_{61,1} to SL_{61,6} and SL_{62,1} to SL_{62,6} are used as multiple pairs of signal lines for two-phase signal transmission, two signal lines in a pair of signal lines and one signal line in another pair of signal lines can be equally spaced apart from each other. Thus, these three signal lines can be applied to three-phase signal transmission, and the differential impedances between any two of the three signal lines are substantially equal. As another example, when the signal lines SL_{61,1} to SL_{61,6} and SL_{62,1} to SL_{62,6} are used as multiple trios of signal lines for three-phase signal transmission, the distance between a signal line in a first trio of signal lines and a signal line in a second trio of signal lines can be equal to or substantially equal to the distance between the remaining two signal lines in the first trio of signal lines. Thus, these four signal lines can serve as two pairs of signal lines for two-phase signal transmission, and each pair of signal lines can exhibit substantially the same differential impedance.

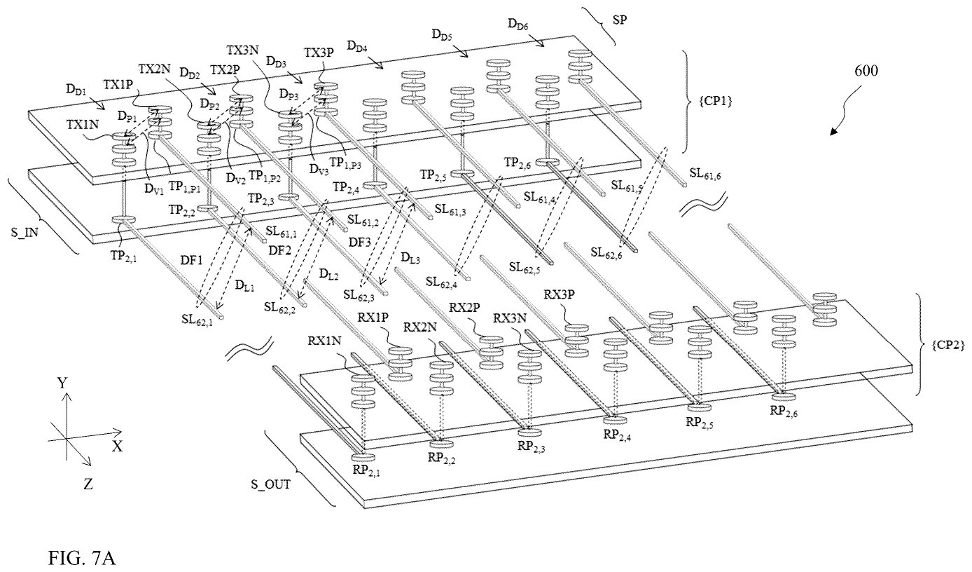

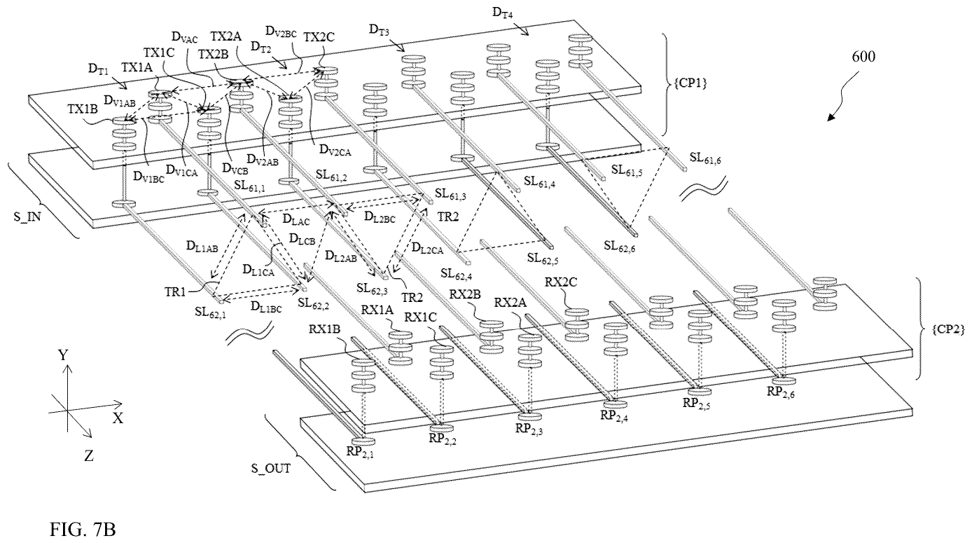

FIG. 7A is a diagram illustrating the signal transmission device 600 shown in FIG. 6A applied for two-phase signal transmission in accordance with some embodiments of the present disclosure. In the present embodiment, the physical layer signal SP may include, but is not limited to, a plurality of D-PHY signals (i.e., the data D_{D1} to D_{D6} associated with differential signaling). The signal lines SL_{61,1} to SL_{61,6} and SL_{62,1} to SL_{62,6} can serve as six pairs of signal lines, in which each pair of signal lines is used to transmit a D-PHY clock signal or a D-PHY data signal.

Referring to FIG. 7A and also to FIG. 6A, by example but not limitation, the signal lines SL_{61,1} and SL_{62,1} can serve as a pair of signal lines DF1 for transmitting the data D_{D1}, the signal lines SL_{61,2} and SL_{62,2} can serve as a pair of signal lines DF2 for transmitting the data D_{D2}, the signal lines SL_{61,3} and SL_{62,3} can serve as a pair of signal lines DF3 for transmitting the data D_{D3}, and so on. The conductive pads TP_{0U,P1} and TP_{0U,N1} can serve as a pair of input terminals TX1P and TX1N for receiving the data D_{D1}, the conductive pads TP_{0U,P2} and TP_{0U,N2} can serve as a pair of input terminals TX2P and TX2N for receiving data D_{D2}, and the conductive pads TP_{0U,P3} and TP_{0U,N3} can serve as a pair of input terminals TX3P and TX3N for receiving data D_{D3}, and so on. The data D_{D1} to D_{D6} may include four D-PHY data signals and two D-PHY clock signals; alternatively, the data D_{D1} to D_{D6} may include five D-PHY data signals and one D-PHY clock signal. However, this is not intended to limit the scope of the present disclosure.

In the present embodiment, different pairs of signal lines can exhibit the same or substantially the same differential impedances. For example, the distances between different pairs of signal lines can be equal or substantially equal, so that the data D_{D1} to D_{D6} can experience substantially the same differential impedance when transmitted along the Z-axis (e.g., a horizontal direction). In other words, the distances D_{L1} between the signal lines SL_{61,1} and SL_{62,1}, the distances D_{L2} between the signal lines SL_{61,2} and SL_{62,2}, and the distance D_{L3} between the signal lines SL_{61,3} and SL_{62,3} can be equal or substantially equal.

The configuration of the cross-layer transmission paths at the input side S_IN (i.e., the conductive paths {CP1}) in the XZ-plane can correspond to the configuration of the signal lines SL_{61,1} to SL_{61,6} and SL_{62,1} to SL_{62,6} in the XY-plane, thus maintaining consistent impedance between the cross-layer transmission paths at the input side S_IN. In the present embodiment, the distance between two conductive vias (or two conductive pads) coupled to each pair of input terminals can be the same or substantially the same. Thus, the cross-layer transmission paths corresponding to different pairs of input terminals can exhibit the same or substantially the same differential impedance. In other words, the data D_{D1} to D_{D6} can experience substantially the same differential impedance when transmitted along the Y-axis (e.g., a vertical direction).

In some examples, the distance D_{V1}, the distance D_{V2} and the distance D_{V3} can be equal or substantially equal. The distance D_{V1} can be a distance from one conductive via between the conductive pads TP_{0U,P1} and TP_{0L,P1} to another conductive via between the conductive pads TP_{0U,N1} and TP_{0L,N1}; additionally or alternatively, the distance D_{V1} can be a distance from one conductive via between the conductive pads TP_{0L,P1} and TP_{1,P1} to another conductive via between the conductive pads TP_{0L,N1} and TP_{1,N1}. The distance D_{V2} can be a distance from one conductive via between the conductive pads TP_{0U,P2} and TP_{0L,P2} to another conductive via between the conductive pads TP_{0U}, _{N2} and TP_{0L}, _{N2}; additionally or alternatively, the distance D_{V2} can be a distance from one conductive via between the conductive pads TP_{0L}, _{P2} and TP_{1,P2} to another conductive via between the conductive pads TP_{0L}, _{N2} and TP_{1,N2}. The distance D_{V3} can be a distance from one conductive via between the conductive pads TP_{0U,P3} and TP_{0L,P3} to another conductive via between the conductive pads TP_{0U,N3} and TP_{0L,N3}; additionally or alternatively, the distance D_{V3} can be a distance from one conductive via between the conductive pads TP_{0L,P3} and TP_{1,P3} to another conductive via between the conductive pads TP_{0L,N3} and TP_{1,N3}.

In some examples, the distance D_{P1} between the conductive pads TP_{0U,P1} and TP_{0U,N1}, the distance D_{P2} between the conductive pads TP_{0U,P2} and TP_{0U,N2}, and the distance D_{P3} between the conductive pads TP_{0U,P3} and TP_{0U,N3} can be equal or substantially equal. In some examples, the distance between the conductive pads TP_{0L,P1} and TP_{0L,N1}, the distance between the conductive pads TP_{0L,P2} and TP_{0L,N2}, and the distance between the conductive pads TP_{0L,P3} and TP_{0L,N3} can be equal or substantially equal. In some examples, the distance between the conductive pads TP_{1,P1} and TP_{1,N1}, the distance between the conductive pads TP_{1,P2} and TP_{1,N2}, and the distance between the conductive pads TP_{1,P3} and TP_{1,N3} can be equal or substantially equal.

Similarly, the configuration of the cross-layer transmission paths at the output side S_OUT (i.e., the conductive paths {CP2}) in the XZ-plane can correspond to the configuration of the signal lines SL_{61,1} to SL_{61,6} and SL_{62,1} to SL_{62,6} in the XY-plane, thus maintaining consistent impedance between the cross-layer transmission paths at the output side S_OUT. The conductive pads RP_{0U,P1} and RP_{0U,N1} can serve as a pair of output terminals RX1P and RX1N, the conductive pads RP_{0U,P2} and RP_{0U,N2} can serve as a pair of output terminals RX2P and RX2N, and the conductive pads RP_{0U,P3} and RP_{0U,N3} can serve as a pair of output terminals RX3P and RX3N, and so on. As those skilled in the art can appreciate the configuration details of the cross-layer transmission paths at the output side S_OUT after reading the above paragraphs directed to FIG. 6A, FIG. 6B and FIG. 7A, similar description is not repeated here for brevity.

FIG. 7B is a diagram illustrating the signal transmission device 600 shown in FIG. 6A applied for three-phase signal transmission in accordance with some embodiments of the present disclosure. In the present embodiment, the physical layer signal SP may include, but is not limited to, a plurality of C-PHY signals (i.e., the data D_{T1} to D_{T4} associated with three-phase encoding). The signal lines SL_{61,1} to SL_{61,6} and SL_{62,1} to SL_{62,6} can serve as four trios of signal lines, in which each trio of signal lines is used to transmit a symbol defined by the C-PHY standard (i.e., the data D_{T1}/D_{T2}/D_{T3}/D_{T4}).

Referring to FIG. 7B and also to FIG. 6A, by example but not limitation, the signal lines SL_{61,1}, SL_{62,1} and SL_{62,2} can serve as a first trio of signal lines for transmitting the data D_{T1}, the signal lines SL_{62,3}, SL_{61,2}, and SL_{61,3} can serve as a second trio of signal lines for transmitting the data D_{T2}, and so on. The conductive pads TP_{0U,P1}, TP_{0U,N1} and TP_{0U,N2} can serve as a trio of input terminals TX1A, TX1B and TX1C for receiving the data D_{T1}. The data D_{T1} can include a first differential signal between the input terminals TX1A and TX1B, a second differential signal between the input terminals TX1B and TX1C, and a third differential signal between the input terminals TX1A and TX1C. Similarly, the conductive pads TP_{0U,N3}, TP_{0U,P2} and TP_{0U,P3} can serve as a trio of input terminals TX2A, TX2B, and TX2C for receiving the data D_{T2}. The data D_{T2} can include a first differential signal between the input terminals TX2A and TX2B, a second differential signal between the input terminals TX2B and TX2C, and a third differential signal between the input terminals TX2A and TX2C. However, this is not intended to limit the scope of the present disclosure.

In the present embodiment, any two signal lines within each trio of signal lines can exhibit the same or substantially the same differential impedance. For example, the distances between any two signal lines in each trio of signal lines can be equal or substantially equal, so that three differential signal components within each data can experience substantially the same differential impedance when transmitted along the Z-axis (e.g., a horizontal direction). With respect to a trio of signal lines for transmitting the data D_{T1}, the signal lines SL_{61,1}, SL_{62,1} and SL_{62,2} can be equally spaced apart from each other; with respect to a trio of signal lines for transmitting the data D_{T2}, the signal lines SL_{62,3}, SL_{61,2} and SL_{61,3} can be equally spaced apart from each other. Additionally or alternatively, the signal lines SL_{61,1} and SL_{62,2} (included in one trio of signal lines) and the signal line SL_{61,2} (included in another trio of signal lines) can be equally spaced apart from each other. In other words, three signal lines from two pairs of signal lines shown in FIG. 7A can serve as a trio of signal lines, and can be equally spaced apart from each other.

The configuration of the cross-layer transmission paths at the input side S_IN (i.e., the conductive paths {CP1}) in the XZ-plane can correspond to the configuration of the trios of signal lines in the XY-plane. The impedance characteristics of cross-layer transmission paths related to a trio of input terminals can correspond to the impedance characteristics of a trio of signal lines related to the trio of input terminals. In the present embodiment, the ratio of respective distances between conductive vias (or conductive pads) corresponding to a trio of input terminals can be proportional to the ratio of respective distances between three signal lines corresponding to the trio of input terminals. For example, the distances between any two of conductive vias connected to a trio of input terminals can be equal or substantially equal, and/or the distances between any two of conductive pads connected to a trio of input terminals can be equal or substantially equal. Thus, the cross-layer transmission paths corresponding to different trios of input terminals can exhibit the same or substantially the same differential impedance. The data D_{T1} to D_{T4} can experience substantially the same differential impedance when transmitted along the Y-axis (e.g., a vertical direction)

In the present embodiment, a ratio of the distances between conductive vias coupled to the input terminals TX1A, TX1B and TX1C (e.g. the associated conductive vias between the conductive pads TP_{0U,P1} and TP_{0L,P1}, or the associated conductive vias between the conductive pads TP_{0L,P1} and TP_{1,P1}) can be proportional to a ratio of the distances between the signal lines SL_{61,1}, SL_{62,1} and SL_{62,2} (e.g., D_{V1AB}: D_{V1AB}:D_{V1CA}=D_{L1AB}:D_{L1AB}:D_{L1CA}). Similarly, a ratio of the distances between conductive vias coupled to the input terminals TX2A, TX2B and TX2C (e.g. the associated conductive vias between the conductive pads TP_{0U,P2} and TP_{0L,P2}, or the associated conductive vias between the conductive pads TP_{0L,P2} and TP_{1,P2}) can be proportional to a ratio of the distances between the signal lines SL_{62,3}, SL_{61,2} and SL_{61,3} (e.g., D_{V2AB}:D_{V2AB}:D_{V2CA}=D_{L2AB}:D_{L2AB}:D_{L2CA}).

In some embodiments, a ratio of the distances between conductive vias coupled to the input terminals TX1A, TX1C and TX2B (i.e., input terminals corresponding to different trios of signal lines) can be proportional to a ratio of the distances between the signal lines SL_{61,1}, SL_{62,2} and SL_{61,2} (e.g., D_{V1CA}:D_{V1CA}:D_{VAC}=D_{L1CA}:D_{L1CA}:D_{LAC}).

In addition, the respective distances between the conductive pads TP_{0U,P1}, TP_{0U,N1} and TP_{0U,N2} (or the respective distances between the conductive pads TP_{0L,P1}, TP_{0L,N1} and TP_{0L,N2}) can have a ratio (e.g., D_{V1AB}:D_{V1AB}:D_{V1CA}) proportional to a ratio of the respective distances between the signal lines SL_{61,1}, SL_{62,1} and SL_{62,2} (e.g., DL1AB:D_{L1AB}:D_{L1CA}). The respective distances between the conductive pads TP_{1,P1}, TP_{1,N1} and TP_{1,N2} can have a ratio (e.g., DV1AB: D_{V1AB}: DV1CA) proportional to a ratio of the respective distances between the signal lines SL_{61,1}, SL_{62,1} and SL_{62,2} (e.g., DL1AB: D_{L1AB}: DL1CA). Similarly, the respective distances between the conductive pads TP_{0U}, _{N3}, TP_{0U}, _{P2} and TP_{0U}, _{P3} (or the respective distances between the conductive pads TP_{0L}, _{N3}, TP_{0L}, _{P2} and TP_{0L}, _{P3}) can have a ratio (e.g., D_{V2AB}:D_{V2AB}:D_{V2CA}) proportional to a ratio of the distances between the signal lines SL_{62,3}, SL_{61,2} and SL_{61,3} (e.g., D_{L2AB}:D_{L2AB}:D_{L2CA}). The respective distances between the conductive pads TP_{1,N3}, TP_{1,P2} and TP_{1,P3} can have a ratio (e.g., D_{V2AB}:D_{V2AB}:D_{V2CA}) proportional to a ratio of the respective distances between the signal lines SL_{62,3}, SL_{61,2} and SL_{61,3} (e.g., D_{L2}AB:D_{L2AB}:D_{L2CA}).

In some embodiments, the respective distances between the conductive pads TP_{0U,P1}, TP_{0U,N2} and TP_{0U,P2} (or the conductive pads TP_{1,P1}, TP_{1,N2} and TP_{1,P2}), which correspond to different trios of signal lines, can have a ratio (e.g., D_{V1CA}:D_{V1CA}:D_{VAC}) proportional to a ratio of the respective distances between the signal lines SL_{61,1}, SL_{62,2} and SL_{61,2} (e.g., D_{L1CA}:D_{LCB}:D_{LAC}).

Similarly, the configuration of the cross-layer transmission paths at the output side S_OUT (i.e., the conductive paths {CP2}) in the XZ-plane can correspond to the configuration of the trios of signal lines in the XY-plane. The impedance characteristics of cross-layer transmission paths related to a trio of output terminals can correspond to the impedance characteristics of a corresponding trio of signal lines. The conductive pads RP_{0U,P1}, RP_{0U,N1} and RP_{0U,N2} can serve as a trio of output terminals RX1A, RX1B and RX1C, and the conductive pads RP_{0U,N3}, RP_{0U,P2} and RP_{0U,P3} can serve as a trio of output terminals RX2A, RX2B and RX2C. As those skilled in the art can appreciate the configuration details of the cross-layer transmission paths at the output side S_OUT after reading the above paragraphs directed to FIG. 6A, FIG. 6B, FIG. 7A and FIG. 7B, similar description is not repeated here for brevity.

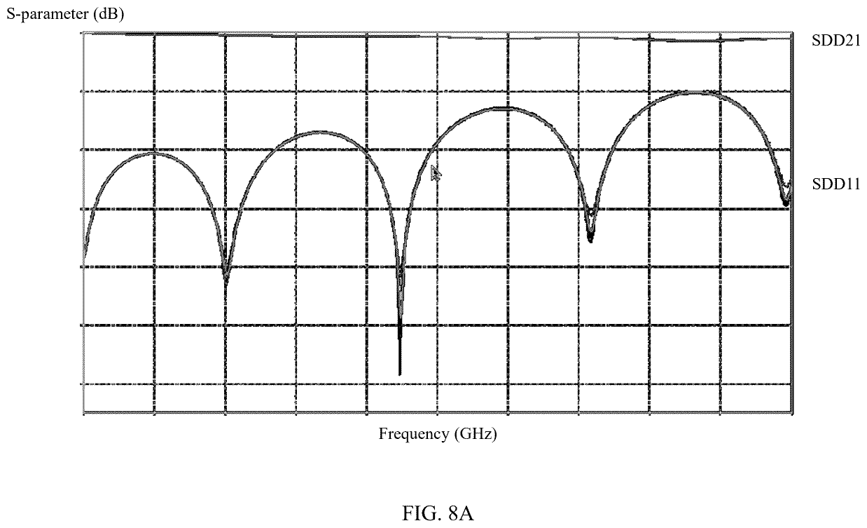

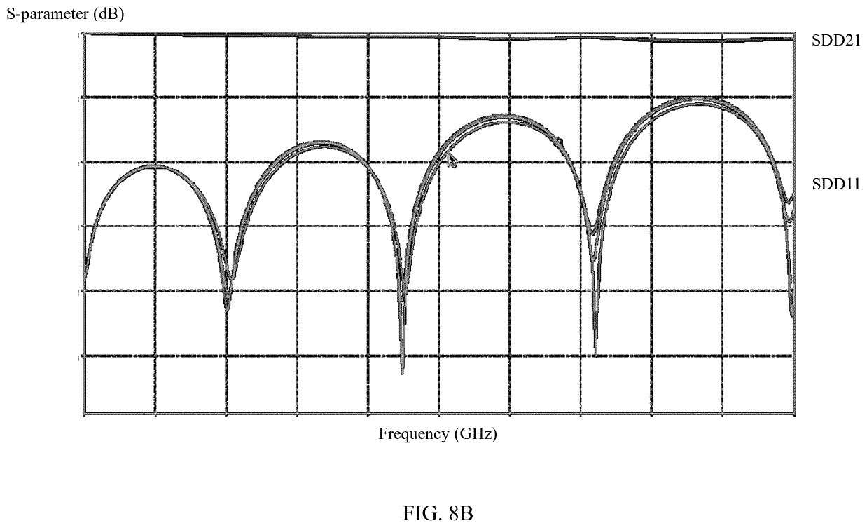

The proposed signal routing structure can effectively enhance impedance consistency in both two-phase and three-phase signal transmission. FIG. 8A is a diagram illustrating frequency responses of S-parameters of the signal transmission device 600 shown in FIG. 6A employed in two-phase signal transmission shown in FIG. 7A (e.g. D-PHY signal transmission) in accordance with some embodiments of the present disclosure. FIG. 8B is a diagram illustrating frequency responses of S-parameters of the signal transmission device 600 shown in FIG. 6A employed in three-phase signal transmission shown in FIG. 7B (e.g. C-PHY signal transmission) in accordance with some embodiments of the present disclosure.

Firstly, referring to FIG. 8A and also to FIG. 7A, the S-parameter SDD11 indicates the return loss associated with six differential signal pairs, and the S-parameter SDD21 indicates the insertion loss associated with the six differential signal pairs. A differential signal pair may include a pair of signal lines (e.g. the pair of signal lines DF1), conductive paths connecting a corresponding pair of input terminals to the pair of signal lines, and conductive paths connecting the pair of signal lines to a corresponding pair of output terminals.

The return loss can represent power loss due to signal reflection, and can be measured at a pair of input terminals (e.g., the input terminals TX1P and TX1N). The insertion loss can represent power loss during signal transmission from a pair of input terminals (e.g., the input terminals TX1P and TX1N) to a corresponding pair of output terminals (e.g., the output terminals RX1P and RX1N). In the present embodiment, the S-parameter curves of the six differential signal pairs overlap significantly, exhibiting a high degree of consistency. In other words, each differential signal pair is well-matched in terms of impedance, and the six differential signal pairs have very similar insertion loss and return loss characteristics.

Referring to FIG. 8B and also to FIG. 7B, the S-parameter SDD11 indicates the return loss associated with four trios of signal paths, and the S-parameter SDD21 indicates the insertion loss associated with the four trios of signal paths. A trio of signal paths may include a trio of signal lines (e.g. the trio of signal lines TR1), conductive paths connecting a corresponding trio of input terminals to the trio of signal lines, and conductive paths connecting the trio of signal lines to a corresponding trio of output terminals.

The return loss can represent power loss due to signal reflection, and can be measured between any two input terminals within a trio of input terminals. The insertion loss can represent power loss during signal transmission from two input terminals within a trio of input terminals to corresponding two output terminals within a trio of output terminals. In the present embodiment, the S-parameter curves of the four trio of signal paths overlap significantly, exhibiting a high degree of consistency. In other words, each pair of signal paths is well-matched in terms of impedance, and the four trios of signal paths have very similar insertion loss and return loss characteristics.

Note that the frequency responses of S-parameters SDD11/SDD21 shown in FIG. 8B closely resemble those shown in FIG. 8A. Compared to a two-dimensional signal line configuration, in which multiple signal lines are arranged in the same signal layer, the proposed three-dimensional signal line configuration not only can be compatible with both two-phase and three-phase signal transmission, but also can maintain excellent impedance consistency during both types of signal transmission, resulting in high signal integrity.

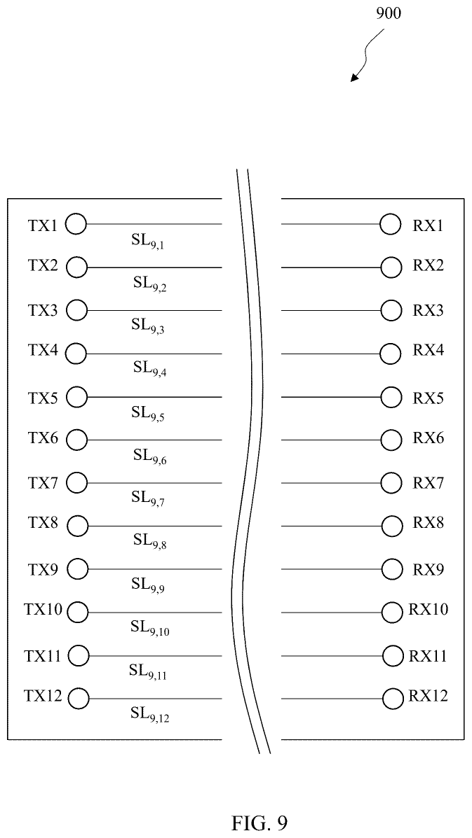

For example, referring to FIG. 9, a signal transmission device 900 employing a two-dimensional signal line configuration is illustrated in accordance with some embodiments of the present disclosure. In the present embodiment, a plurality of signal lines SL_{9,1} to SL_{9,12} are arranged on the same signal layer. Each signal line is configured to transmit a signal from an input terminal (i.e., one of the input terminals TX1 to TX12) to a corresponding output terminal (i.e., one of the output terminals RX1 to RX12). When applied to two-phase signal transmission, the signal lines SL_{9,1} and SL_{9,2} can serve as a first differential signal pair, the signal lines SL_{9,3} and SL_{9,4} can serve as a second differential signal pair, the signal lines SL_{9,5} and SL_{9,6} can serve as a third differential signal, and so on. When applied to three-phase signal transmission, the signal lines SL_{9,1} to SL_{9,3} can serve as a first trio of signal lines, the signal lines SL_{9,4} to SL_{9,6} can serve as a second trio of signal lines, and so on.

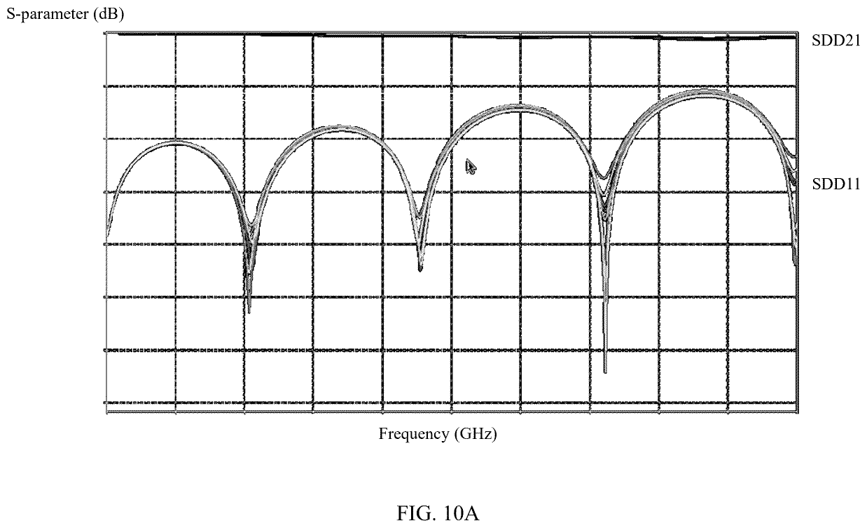

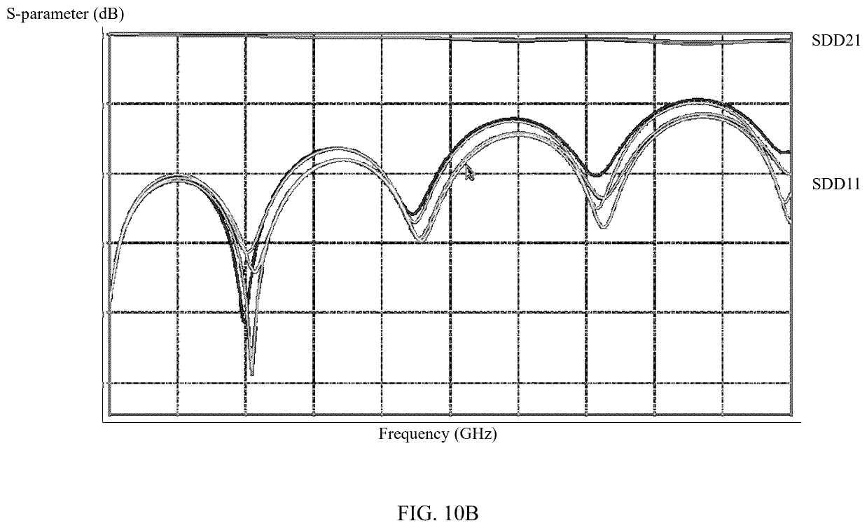

FIG. 10A is a diagram illustrating frequency responses of S-parameters of the signal transmission device 900 shown in FIG. 9 employed in two-phase signal transmission in accordance with some embodiments of the present disclosure. Compared to the S-parameter curves shown in FIG. 8A, the S-parameter curves of the six differential signal pairs shown in FIG. 10A show low consistency. In other words, the signal transmission device 900 shown in FIG. 9 employing the two-dimensional signal line configuration exhibits reduced impedance consistency in two-phase signal transmission.

FIG. 10B is a diagram illustrating frequency responses of S-parameters of the signal transmission device 900 shown in FIG. 9 employed in three-phase signal transmission in accordance with some embodiments of the present disclosure. Compared to the S-parameter curves shown in FIG. 8B, the S-parameter curves of the four trios of signal lines shown in FIG. 10B show low consistency. In other words, the signal transmission device 900 shown in FIG. 9 employing the two-dimensional signal line configuration exhibits reduced impedance consistency in three-phase signal transmission. In addition, the frequency responses of S-parameters SDD11/SDD21 shown in FIG. 10B are noticeably distinct from those shown in FIG. 10A. The two-dimensional signal line configuration would be unable to maintain impedance consistency for both C-PHY and D-PHY signal transmission.

With the use of the three-dimensional signal line configuration, the proposed signal transmission scheme can meet the combo requirements for both two-phase and three-phase signal transmission (e.g., D-PHY and C-PHY signal transmission), thereby maintaining impedance consistency and signal integrity for both two-phase and three-phase signal transmission on shared routing traces.

As used herein, the terms “substantially” are used to describe and account for small variations. When used in conduction with an event or circumstance, the terms can refer to instances in which the event of circumstance occurs precisely as well as instances in which the event or circumstance occurs to a close approximation. As used herein with respect to ta given value or range, the term “substantially” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. In addition, when referring to numerical values or characteristics as “substantially” the same, the term can refer to the values lying within ±10%, ±5%, ±1%, or ±0.5% of an average of the values.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A signal transmission device, comprising:
a dielectric layer;
a first signal layer and a second signal layer, wherein the dielectric layer is stacked between the first signal layer and the second signal layer; and
a set of signal lines arranged in parallel along a predetermined direction, the set of signal lines being configured to transmit a physical layer signal, the set of signal lines comprising a first signal line, a second signal line, a third signal line and a fourth signal line,
wherein the first signal line is arranged in the first signal layer; the second signal line and the third signal line are arranged in the second signal layer; a distance from the fourth signal line to one of the first signal line and the third signal line is equal to a distance from the second signal line to the other of the first signal line and the third signal line.

2. The signal transmission device of claim 1, wherein the physical layer signal comprises data associated with three-phase encoding; the first signal line, the second signal line and the third signal line are configured to transmit the data.

3. The signal transmission device of claim 1, wherein the physical layer signal comprises first data and second data associated with differential signaling; the fourth signal line and the one of the first signal line and the third signal line are configured to transmit the first data; the second signal line and the other of the first signal line and the third signal line are configured to transmit the second data.

4. The signal transmission device of claim 1, wherein the signal transmission device is a package substrate, a printed circuit board, or an integrated circuit substrate.

5. The signal transmission device of claim 1, wherein a distance between the first signal line and the second signal line is equal to a distance between the first signal line and the third signal line.

6. The signal transmission device of claim 1, wherein the first signal line, the second signal line and the third signal line are equally spaced apart from each other.

7. The signal transmission device of claim 1, wherein the fourth signal line is arranged in the first signal layer; a distance from the fourth signal line to the third signal line is equal to a distance from the second signal line to the first signal line.

8. The signal transmission device of claim 1, wherein the fourth signal line is arranged in the first signal layer; a distance from the fourth signal line to the first signal line is equal to a distance from the second signal line to the third signal line.

9. The signal transmission device of claim 1, wherein the fourth signal line is arranged in the second signal layer; a distance from the fourth signal line to the third signal line is equal to a distance from the second signal line to the first signal line.

10. The signal transmission device of claim 1, further comprising:
a third signal layer, wherein the fourth signal line is arranged in the third signal layer, the first layer is stacked between the second layer and the third layer, and a distance from the fourth signal line to the first signal line is equal to a distance from the second signal line to the third signal line.

11. The signal transmission device of claim 1, wherein the first signal layer is stacked above the second signal layer, and the signal transmission device further comprises:
a first conductive pad, arranged in the first signal layer and connected to an end of the first signal line;
a second conductive pad, arranged in the first signal layer;
a third conductive pad, arranged in the first signal layer;
a first conductive via, penetrating through the dielectric layer to electrically connect the second conductive pad to an end of the second signal line; and
a second conductive via, penetrating through the dielectric layer to electrically connect the third conductive pad to an end of the third signal line;
wherein a ratio of respective distances between the first conductive pad, the second conductive pad and the third conductive pad is proportional to a ratio of respective distances between the first signal line, the second signal line and the third signal line.

12. The signal transmission device of claim 1, wherein the first signal layer is stacked above the second signal layer, and the signal transmission device further comprises:
a first conductive pad, arranged in the first signal layer and connected to an end of the first signal line;
a second conductive pad, arranged in the first signal layer;
a third conductive pad, arranged in the first signal layer and connected to an end of the fourth signal line; and
a conductive via, penetrating through the dielectric layer to electrically connect the second conductive pad to an end of the third signal line;
wherein a ratio of respective distances between the first conductive pad, the second conductive pad and the third conductive pad is proportional to a ratio of respective distances between the first signal line, the third signal line and the fourth signal line.

13. A signal transmission device, comprising:
a plurality of signal layers, stacked one above another;
a first trio of signal lines configured for transmitting first data associated with three-phase encoding, at least two signal lines in the first trio of signal lines being located in different signal layers, each signal line in the first trio of signals line being arranged along a predetermined direction; and
a second trio of signal lines configured for transmitting second data associated with three-phase encoding, at least two signal lines in the second trio of signal lines being located in different signal layers, each signal line in the second trio of signals line being arranged along the predetermined direction, wherein a distance from one signal line in the second trio of signal lines to one signal line in the first trio of signal lines is equal to a distance between the other two signal lines in the first trio of signal lines.

14. The signal transmission device of claim 13, wherein three signal lines in each trio of signal lines are equally spaced apart from each other.

15. The signal transmission device of claim 13, wherein each trio of signal lines comprises a first signal line, a second signal line and a third signal line; the first signal line is located in a first signal layer, and each of the second signal line and the third signal line is located in a second signal layer stacked below the first signal layer;
the signal transmission device further comprises:
a first conductive pad, arranged in the first signal layer and connected to an end of the first signal line;
a second conductive pad, arranged in the first signal layer;
a third conductive pad, arranged in the first signal layer;
a first conductive via, electrically connected between the second conductive pad and an end of the second signal line; and
a second conductive via, electrically connected between the third conductive pad and an end of the third signal line;
wherein a ratio of respective distances between the first conductive pad, the second conductive pad and the third conductive pad is proportional to a ratio of respective distances between the first signal line, the second signal line and the third signal line.

16. The signal transmission device of claim 13, wherein the first trio of signal lines comprises a first signal line, a second signal line and a third signal line; the first signal line is located in a first signal layer, and each of the second signal line and the third signal line is located in a second signal layer stacked below the first signal layer; a fourth signal line in the second trio of signal lines are located in the first layer; the signal transmission device further comprises:
a first conductive pad, arranged in the first signal layer and connected to an end of the first signal line;
a second conductive pad, arranged in the first signal layer;
a third conductive pad, arranged in the first signal layer;
a fourth conductive pad, arranged in the first signal layer and connected to an end of the fourth signal line;
a first conductive via, electrically connected between the second conductive pad and an end of the second signal line; and
a second conductive via, electrically connected between the third conductive pad and an end of the third signal line;
wherein a distance between the first conductive pad and the second conductive pad is equal to a distance between the fourth conductive pad and the third conductive pad.

17. A signal transmission device, comprising:
a first signal layer and a second signal layer stacked one above the other;
a first pair of signal lines configured for transmitting first data associated with differential signaling, wherein a first signal line and a second signal line included in the first pair of signal lines are located in the first signal layer and the second signal layer respectively, and arranged along a predetermined direction; and
a second pair of signal lines configured for transmitting second data associated with differential signaling, wherein a third signal line and a fourth signal line included in the second pair of signals line are arranged along the predetermined direction; three of the first signal line, the second signal line, the third signal line and the fourth signal line are equally spaced apart from each other.

18. The signal transmission device of claim 17, wherein the third signal line is located in the first signal layer, and the fourth signal line is located in the second signal layer.

19. The signal transmission device of claim 18, wherein the signal transmission device further comprises:
a first conductive pad, arranged in the first signal layer and connected to an end of the first signal line;
a second conductive pad, arranged in the first signal layer;
a third conductive pad, arranged in the first signal layer and connected to an end of the third signal line;
a fourth conductive pad, arranged in the first signal layer;
a first conductive via, electrically connected between the second conductive pad and an end of the second signal line; and
a second conductive via, electrically connected between the fourth conductive pad and an end of the fourth signal line;
wherein a distance between the first conductive pad and the second conductive pad is equal to a distance between the third conductive pad and the fourth conductive pad.

20. The signal transmission device of claim 17, further comprising:
a third signal layer, wherein the first signal layer, the second signal layer and the third signal layer are stacked one above the other;
wherein the third signal line is located in one of the first signal layer and the second signal layer, and the fourth signal line is located in the third signal layer.
